(19) United States
(12) Patent Application Publication
(10) Pub. No.: US 2023/0327711 A1
(43) Pub. Date: Oct. 12, 2023

(54) ELECTRONIC DEVICE FOR CONTROLLING PHASE DIFFERENCE OF POWER PROVIDED TO RECTIFIER, AND METHOD FOR CONTROLLING SAME

(71) Applicant: Samsung Electronics Co., Ltd., Suwon-si (KR)

(72) Inventors: Chongmin LEE, Suwon-si (KR); Sungku YEO, Suwon-si (KR); Kangho BYUN, Suwon-si (KR); Jaesun SHIN, Suwon-si (KR); Jeongman LEE, Suwon-si (KR); Hyoseok HAN, Suwon-si (KR)

(21) Appl. No.: 18/335,015

(22) Filed: Jun. 14, 2023

Related U.S. Application Data
(63) Continuation of application No. PCT/KR2021/017346, filed on Nov. 24, 2021.

(30) Foreign Application Priority Data
Jan. 20, 2021 (KR) 10-2021-0008118

(51) Int. Cl. H04B 5/00; H02J 50/12

(52) U.S. Cl. CPC H04B 5/0037; H04B 5/0081; H02J 50/12

(57) ABSTRACT

An electronic device may include: a resonance circuit including a battery, a coil, and a capacitor, and configured to receive power wirelessly; a rectifying circuit including multiple transistors, and configured to rectify alternating current power provided from the resonance circuit into direct current power; and a control circuit, wherein the control circuit is configured to: identify a difference between the phase of voltage and the phase of current of the alternating current power provided from the resonance circuit during wireless reception of power from an external electronic device; and perform impedance matching by controlling the bias voltage of at least one of the multiple transistors on the basis that the difference between the phase of voltage and the phase of current satisfies a designated condition.

### CROSS-REFERENCE TO RELATED APPLICATIONS

This application is a continuation of International Application No. PCT/KR2021/017346 designating the United States, filed on Nov. 24, 2021, in the Korean Intellectual Property Receiving Office and claiming priority to Korean Patent Application No. 10-2021-0008118, filed on Jan. 20, 2021, in the Korean Intellectual Property Office, the disclosures of which are incorporated by reference herein in their entireties.

### BACKGROUND

### Field

Various example embodiments relate to an electronic device controlling the phase difference of power provided to a rectifier and/or a control method thereof.

### Description of Related Art

Recently, as wireless charging technology develops, methods for performing charging by supplying power to one charger for various electronic devices are being researched.

Such wireless recharging technology adopts wireless power transmission/reception. For example, it enables an electronic device to be automatically charged by simply placing the electronic device on a recharging pad.

Wireless charging may be implemented in a few different types, including use of electromagnetic induction, resonance, and radio frequency (RF)/microwave radiation.

Wireless charging-based power transmission methods transmit power between a first coil of the transmission end and a second coil of the reception end. The transmission end generates a magnetic field, and a current is induced and resonated according to variations in magnetic field in the reception end, creating energy.

Wireless charging technology adopting electromagnetic induction or magnetic resonance schemes are recently in wide use for smartphones or such electronic devices. If a power transmitting unit (PTU) (e.g., a wireless charging pad) and a power receiving unit (PRU) (e.g., a smartphone) come in contact or close to each other within a predetermined distance, the battery of the power receiving unit may be charged by electromagnetic induction or electromagnetic resonance between the transmission coil of the power transmitting unit and the reception coil of the power receiving unit.

### SUMMARY

An electronic device (e.g., wireless power reception device) may wirelessly receive power from a wireless power transmission device through a resonance circuit (in other words, a resonator). For example, the electronic device may adjust the impedance of the resonance circuit to allow the resonance circuit to match a specific frequency (e.g., impedance matching through an impedance matching circuit) and wirelessly receive power.

If the coupling coefficient (k) and/or mutual inductance (M) between the electronic device and the wireless power transmission device is varied due to, e.g., a change in the distance between the electronic device and the wireless power transmission device, a phase difference may occur in the power provided to another component (e.g., rectifier) through the resonance circuit of the electronic device. For example, a difference may occur between the phase of the voltage and the phase of the current of the power provided through the resonance circuit. Thus, the power conversion efficiency (e.g., AC/DC conversion efficiency) of the rectifier may be reduced.

According to various example embodiments, there may be provided an electronic device and/or a control method thereof, which control the bias voltage of a switch (e.g., transistor) constituting a rectifier if a phase difference occurs between the voltage and current of the power provided from the resonance circuit.

According to various example embodiments, an electronic device may comprise a battery, a resonance circuit including a coil and a capacitor and configured to wirelessly receive power, a rectification circuit including a plurality of transistors and configured to rectify AC power provided from the resonance circuit into DC power, and a control circuit. The control circuit may be configured to identify a difference between a phase of voltage and a phase of current of the AC power provided from the resonance circuit while the power is wirelessly received from an external electronic device and perform impedance matching by controlling a bias voltage of at least one of the plurality of transistors based on the difference between the phase of voltage and the phase of current meeting a designated condition.

According to various example embodiments, a method for controlling an electronic device may comprise identifying a difference between a phase of voltage and a phase of current of AC power provided from a resonance circuit of the electronic device while the power is wirelessly received from an external electronic device and performing impedance matching by controlling a bias voltage of at least one of a plurality of transistors included in a rectification circuit of the electronic device based on the difference between the phase of voltage and the phase of current meeting a designated condition.

According to various example embodiments, a computer-readable non-volatile recording medium may store instructions to, when executed, enable at least one processor of an electronic device to identify a difference between a phase of voltage and a phase of current of AC power provided from a resonance circuit of the electronic device while the power is wirelessly received from an external electronic device and perform impedance matching by controlling a bias voltage of at least one of a plurality of transistors included in a rectification circuit of the electronic device based on the difference between the phase of voltage and the phase of current meeting a designated condition.

According to various example embodiments, the electronic device may perform impedance matching by controlling the bias voltage of a switch (e.g., transistor) constituting the rectifier.

According to various example embodiments, the electronic device may control the phase difference between the voltage and current of the rectified power by controlling the bias voltage of a switch (e.g., transistor) constituting the rectifier.

Various effects achievable are not limited by the foregoing effects.

### BRIEF DESCRIPTION OF DRAWINGS

The foregoing and other features of example embodiments will become more apparent from the following detailed description of embodiments when read in conjunction with the accompanying drawings. In the drawings, like reference numerals refer to like elements.

FIG. 1 is a view illustrating an electronic device in a network environment according to various example embodiments;

FIG. 2A illustrates a wireless power transmission/reception system according to various example embodiments;

FIG. 2B illustrates components of a wireless power transmission device and an electronic device included in a wireless power transmission/reception system according to various example embodiments;

FIG. 3 is a block diagram illustrating an electronic device according to various example embodiments;

FIG. 4 illustrates loop circuits of a resonance circuit and a rectification circuit according to various example embodiments;

FIG. 5 illustrates voltage and current waveforms according to various example embodiments;

FIG. 6 is a flowchart illustrating a method for controlling a resonance circuit based on a phase difference between the voltage and current input to the resonance circuit by an electronic device according to various example embodiments;

FIG. 7 is a flowchart illustrating a method for controlling the impedance of a resonance circuit based on a phase difference between voltage and current by an electronic device according to various example embodiments;

FIG. 8A illustrates an example of transistors included in each of a plurality of switches constituting a resonance circuit according to various example embodiments;

FIG. 8B illustrates another example of transistors included in each of a plurality of switches constituting a resonance circuit according to various example embodiments;

FIG. 9 is a flowchart illustrating a method for controlling the bias voltage of transistors included in a resonance circuit based on a phase difference between voltage and current by an electronic device according to various example embodiments;

FIG. 10 is a flowchart illustrating a method for controlling the bias voltage of transistors included in a resonance circuit based on a phase difference between voltage and current by an electronic device according to various example embodiments;

FIG. 11A is a view illustrating a conduction angle when a bias voltage has a first magnitude according to various example embodiments;

FIG. 11B is a view illustrating a conduction angle when a bias voltage has a second magnitude according to various example embodiments;

FIG. 11C is a view illustrating a conduction angle when a bias voltage has a third magnitude according to various example embodiments; and

FIG. 11D is a view illustrating a conduction angle when a bias voltage has a fourth magnitude according to various example embodiments.

### DETAILED DESCRIPTION

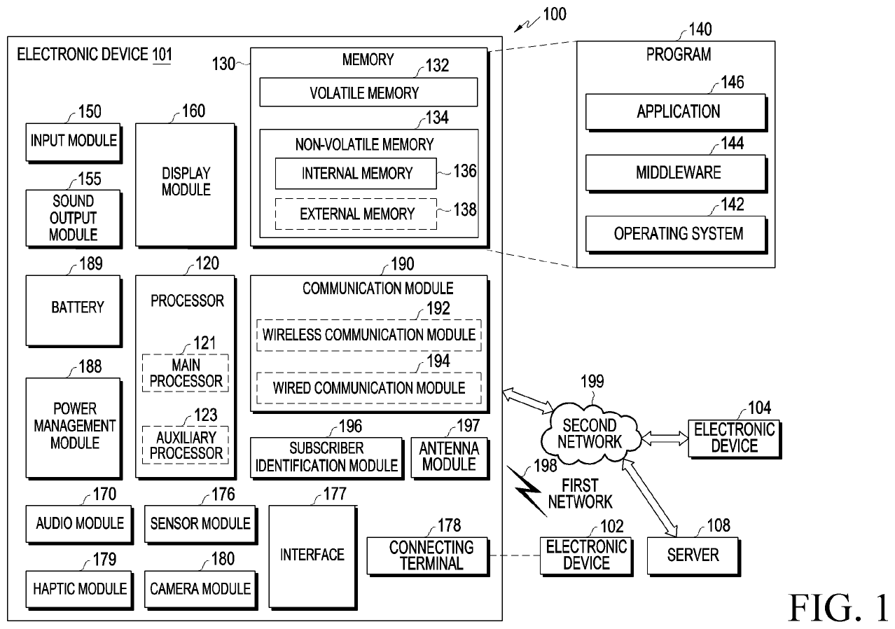

FIG. 1 is a block diagram illustrating an electronic device 101 in a network environment 100 according to various embodiments.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductive body or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

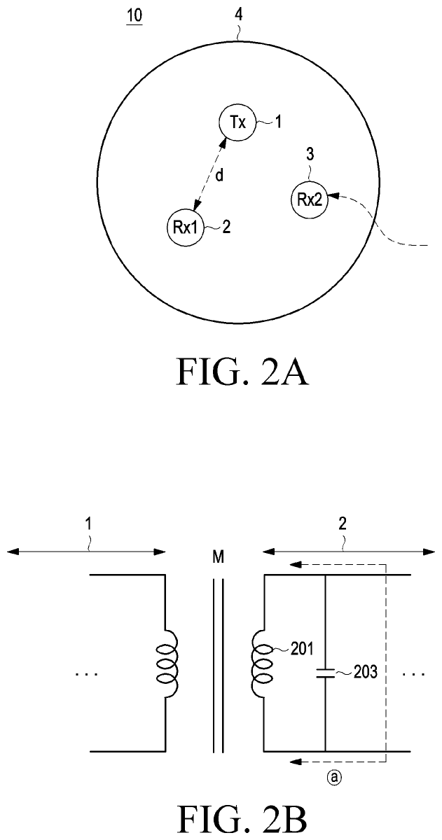

FIG. 2A illustrates a wireless power transmission/reception system 10 according to various embodiments. FIG. 2B illustrates components of a wireless power transmission device 1 and an electronic device 2 (e.g., the electronic device 101 of FIG. 1) included in a wireless power transmission/reception system 10 according to various embodiments.

Referring to FIG. 2A, according to various embodiments, the wireless power transmission/reception system 10 may include a wireless power transmission device 1. The wireless power transmission/reception system 10 may include at least one electronic device 2 and 3 that wirelessly receives power from the wireless power transmission device 1. The electronic devices 2 and 3 may be referred to as wireless power receivers in that they may receive power wirelessly.

According to various embodiments, the wireless power transmission device 1 may wirelessly transmit power to at least one electronic device 2 and 3. The wireless power transmission device 1 may transmit power to the electronic devices 2 and 3 according to various wireless charging schemes.

For example, the wireless power transmission device 1 may transmit power according to the resonance scheme. Adopting the resonance scheme, the wireless power transmission device 1 may include, e.g., a power source, a DC-AC converting circuit (or an amplifying circuit), an impedance matching circuit, at least one capacitor, at least one coil, and an out-band communication circuit (e.g., a Bluetooth low energy (BLE) communication circuit). The at least one capacitor and the at least one coil may constitute a resonance circuit. The wireless power transmission device 1 may be implemented in a scheme defined in, e.g., the alliance for wireless power (A4WP) standards (or air fuel alliance (AFA) standards). The wireless power transmission device 1 may include a coil that is capable of produce a magnetic field when letting an electric current (e.g., AC current) flow thereacross by a resonance or induction scheme. The process of generating a magnetic field through the coil by the wireless power transmission device 1 may be expressed as outputting wireless power, and the process of generating induced electromotive force in the electronic device 2 or 3 based on the generated magnetic field may be expressed as receiving wireless power. It may be expressed as the wireless power transmission device 1 wirelessly transmitting power to the electronic device 2 or 3 through such process. Further, the electronic device 2 or 3 may include a coil that produces an induced electromotive force by the magnetic field generated around and varying in magnitude over time. The process of outputting AC current from the coil or applying AC voltage to the coil as the coil of the electronic device 2 or 3 generates induced electromotive force may be expressed as the electronic device 2 or 3 wirelessly receiving power.

In another example, the wireless power transmission device 1 may transmit power in an electromagnetic scheme. Adopting the electromagnetic scheme, the wireless power transmission device 1 may include, e.g., a power source, a DC-AC converting circuit (or an amplifying circuit), a distributing circuit, a phase shifter, a power transmission antenna array including a plurality of antennas (e.g., patch antennas, dipole antennas, and/or monopole antennas), and an out-band communication circuit (e.g., a BLE communication module). Each of the plurality of antennas may form a radio frequency (RF) wave. The wireless power transmission device 1 may perform beam-forming by adjusting the phase and/or amplitude of an electrical signal input for each antenna. The electronic device 2 or 3 may include antennas capable of outputting electric current using RF waves generated around. The process of the wireless power transmission device 1 producing RF waves may be represented as the wireless power transmission device 1 wirelessly transmitting power. The process of the electronic device 2 or 3 outputting electric current from the antennas using RF waves may be represented as the electronic device 2 or 3 wirelessly receiving power.

For example, the wireless power transmission device 1 may transmit power in an induction scheme. Adopting the induction scheme, the wireless power transmission device 1 may include, e.g., a power source, a direct current (DC)-alternating current (AC) converting circuit, an amplifying circuit, an impedance matching circuit, at least one capacitor, at least one coil, and a communication modulation/demodulation circuit. The at least one capacitor together with the at least one coil may constitute a resonance circuit. The wireless power transmission device 1 may be implemented in a scheme defined in the wireless power consortium (WPC) standards (or Qi standards).

According to various embodiments, the wireless power transmission device 1 may communicate with the electronic device 2 or 3. For example, the wireless power transmission device 1 may communicate with the electronic device 2 or 3 as per an in-band scheme. The wireless power transmission device 1 or the electronic device 2 or 3 may vary the load (or impedance) on the data to be transmitted, according to, e.g., an on/off keying modulation scheme. The wireless power transmission device 1 or the electronic device 2 or 3 may determine data transmitted from its opposite device by measuring a variation in load or impedance based on a variation in the current, voltage, or power across the coil. For example, the wireless power transmission device 1 may communicate with the electronic device 2 or 3 as per an out-band scheme. The wireless power transmission device 1 or the electronic device 2 or 3 may communicate data using a communication circuit (e.g., a BLE communication module) provided separately from the coil or patch antennas. The wireless power transmission device 1 may also transmit media data and, according to implementation, a plurality of different communication circuits (e.g., a BLE communication module, a Wi-Fi module, a Wi-gig module, each comprising communication circuitry) each may transmit or receive media data or wireless power transmission/reception signals.

Referring to FIG. 2A, according to various embodiments, the electronic device 2 may be positioned (or enter) within a chargeable area 4 of a wireless power transmission device 1. According to various embodiments, the electronic device 2 may wirelessly receive power from the wireless power transmission device 1. According to various embodiments, the electronic device 2 may process (e.g., rectify or convert (or regulate)) the power, which is output as voltage is induced at the coil included therein, and transfer the power to the load (e.g., a battery or a charger (hereinafter, charging circuit) for charging the battery) of the electronic device 2.

Referring to FIGS. 2A and 2B, according to an embodiment, the electronic device 2 may wirelessly receive power from the wireless power transmission device 1 through a resonance circuit (e.g., coil 201 and capacitor 203). When the distance d between the electronic device 2 and the wireless power transmission device 1 changes, the coupling coefficient and/or mutual inductance (e.g., M of FIG. 2B) between the wireless power transmission device 1 and the electronic device 2 may vary. Thus, the impedance (e.g., reactance) of the electronic device 2 viewed from the electronic device 2 to the wireless power transmission device 1 (e.g., 0 in FIG. 2B) changes, so that a difference (e.g., difference in time displacement between voltage and current) in phase between the voltage and current of the resonance circuit (e.g., the coil 201 and the capacitor 203) may occur. For example, the resonance circuit (e.g., the capacitor 203) and the rectification circuit (in other words, rectifier) may form a loop circuit. A current may be flowed in the loop circuits formed in the resonance circuit (e.g., the capacitor 203) and the rectification circuit (not shown) based on the power from the resonance circuit (e.g., the coil 201 and the capacitor 203) to the rectification circuit (not shown), and a voltage (e.g., the voltage between the two ends of the capacitor 203) may be applied to the resonance circuit. Meanwhile, a phase difference may occur between the current flowing through the loop circuit and the voltage applied to the resonance circuit. For example, the electronic device 2 may include an impedance matching circuit for impedance matching. However, in a charging environment in which impedance matching by the impedance matching circuit is impossible, the phase difference between the current flowing through the loop circuit and the voltage applied to the resonance circuit may be relatively large. Thus, when the power (e.g., AC power) provided from the resonance circuit (e.g., the coil 201 and the capacitor 203) is rectified by the rectification circuit (not shown), switching loss may occur in the switch (e.g., diode, bipolar junction transistor (BJT), and/or field effect transistor (FET)) included in the rectification circuit (not shown), and the power conversion efficiency may decrease. According to an embodiment, even when another electronic device 3 enters the chargeable area 4, or a metallic material is positioned in the chargeable area 4, the impedance (e.g., reactance) viewed from the electronic device 2 may vary, so that a difference may occur between the phase of voltage and the phase of current of the resonance circuit (e.g., the coil 201 and the capacitor 203), and the power conversion efficiency of the rectification circuit may decrease.

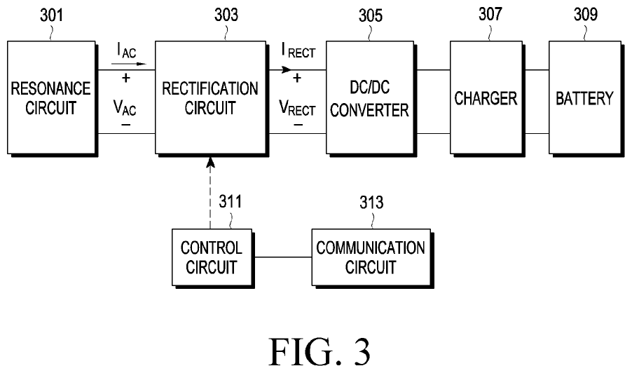

FIG. 3 is a block diagram illustrating an electronic device 101 according to various embodiments.

According to various embodiments, an electronic device 101 may include a resonance circuit 301, a rectification circuit (in other words, a rectifier) 303, a DC/DC converter 305, a charger (in other words, a charging circuit) 307, a battery 309 (e.g., the battery 189 of FIG. 1), a control circuit (in other words, a controller) 311 (e.g., the processor 120 of FIG. 1), and/or a communication circuit 313 (e.g., the communication module 190 of FIG. 1, comprising communication circuitry).

According to various embodiments, power may be generated based on the magnetic field and/or electric field formed by a wireless power reception device (e.g., the wireless power reception device 1 of FIG. 2A). AC power may be generated at the resonance circuit 301 and be transferred to the rectification circuit 303. The resonance circuit 301 may include at least one coil (e.g., the coil 201 of FIG. 2A) and at least one capacitor (e.g., the capacitor 203 of FIG. 2B). A configuration in which at least one coil and at least one capacitor are connected is not limited.

According to various embodiments, the rectification circuit 303 may rectify the AC power received from the resonance circuit 301 into DC power. According to various embodiments, the rectification circuit 303 may include a bridge circuit (e.g., a full-bridge circuit or a half-bridge circuit). According to various embodiments, the rectification circuit 303 may be controlled by the control circuit 311. For example, when the rectification circuit 303 is implemented as a bridge circuit, the on/off state of the switching element (in other words, a switch) of the bridge circuit may be controlled by the control circuit 311. According to various embodiments, the output voltage V_{RECT} of the rectification circuit 303 may be a voltage of power rectified according to the switching of switches included in the rectification circuit.

According to various embodiments, the DC/DC converter 305 may convert or regulate the rectified voltage transferred from the rectification circuit 303. According to various embodiments, the DC/DC converter 305 may provide power having a substantially constant voltage. According to various embodiments, the DC/DC converter 305 may not be included in the electronic device 101 according to implementation. In an embodiment in which the DC/DC converter 305 is not included, the phrase “provided to the DC/DC converter 305” may be understood as the phrase “provided to the charger 307,” and the phrase “provided from the DC/DC converter 305” may be understood as the phrase “provided from the rectification circuit 303”. According to various embodiments, the DC/DC converter 305 may be connected, directly or indirectly, to at least one piece of hardware (or a power management integrated circuit (PMIC) for providing power to the at least one piece of hardware) in addition to the charger 307, and the at least one piece of hardware (or PMIC) may operate using the power from the DC/DC converter 305. According to various embodiments, at least one piece of hardware may be respectively connected to individual PMICs, and the at least one piece of hardware may operate using the power provided through the respective corresponding PMICs. According to various embodiments, the DC/DC converter 305 may be implemented as one or more DC/DC converters, and the number thereof is not limited. According to various embodiments, the DC/DC converter 305 may include a low-dropout (LDO) regulator.

According to various embodiments, the charger 307 may receive power output from the DC/DC converter 305 and may charge the battery 309 connected to the charger 307 using the received power. According to an embodiment, the charger 307 may control the current and/or voltage applied to the battery 309 based on various charging modes (e.g., a constant current (CC) mode, a constant voltage (CV) mode, or a quick charging mode). For example, the charger 307 may control the current (e.g., current for charging the battery 309) and/or voltage applied to the battery 309 based on the charging status of the battery 309. As another example, the charging circuit 207 may control the current and/or voltage applied to the battery 309 based on a user input. For example, when a quick charging mode is selected according to a user input, the charger 307 may control the current and/or voltage according to a setting corresponding to quick fast charging mode.

According to various embodiments, the electronic device 101 may include a PMIC (not shown). The charger 307 may be implemented in a form included in the PMIC. According to an embodiment, the charger 307 may be implemented in a form not included in the PMIC (e.g., a form positioned outside the PMIC).

According to various embodiments, the type of the battery 309 is not limited as long as it is a rechargeable secondary battery.

According to various embodiments, the control circuit 311 may control the rectification circuit 303. For example, when the rectification circuit 303 is implemented as a bridge circuit (e.g., full-bridge circuit or half-bridge circuit), the control circuit 311 may control the on/off state of the switch (e.g., transistor) of the bridge circuit.

According to various embodiments, the control circuit 311 may detect power provided from the resonance circuit 301 to the rectification circuit 303. For example, the control circuit 311 may detect the voltage V_{AC} (e.g., AC voltage) and current I_{AC} (e.g., AC current) of the power provided (e.g., input) from the resonance circuit 301 to the rectification circuit 303. For example, the control circuit 311 may detect the voltage V_{AC} and current I_{AC} using at least one sensor (e.g., current sensor, voltage sensor, and/or power sensor) disposed between the resonance circuit 301 and the rectification circuit 303. The position where the at least one sensor for detecting the voltage V_{AC} and current I_{AC} is not limited to the above-described position.

According to various embodiments, the control circuit 311 may identify the phase difference between the detected voltage V_{AC} and current I_{AC}. For example, the control circuit 311 may identify the phase difference between the voltage V_{AC} and current I_{AC} using a comparator, a phase detector, an analog-digital converter (ADC) sampler, and/or other various components. For example, if the phase of the current I_{AC} is later than the phase of the voltage V_{AC}, it may be identified as a lagging state. For example, if the phase of the current I_{AC} is earlier than the phase of the voltage V_{AC}, it may be identified as a leading state. Further, if the phases are the same, it may be identified as an in-phase state.

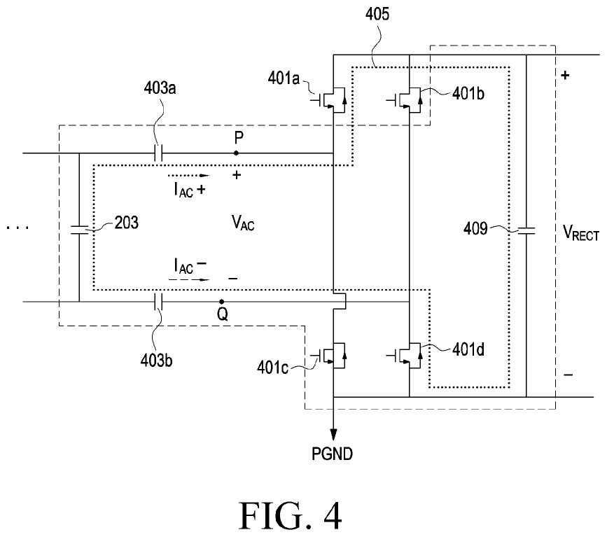

According to various embodiments, the control circuit 311 may control the bias voltage of the switches included in the rectification circuit 303 (e.g., the gate-source voltage V_{gs} of one or more transistors included in each switch) based on identifying the phase difference between the voltage V_{AC} and current I_{AC}. According to various embodiments, the control circuit 311 may perform impedance matching by controlling the bias voltage of the switches included in the rectification circuit 303 (e.g., the gate-source voltage V_{gs} of one or more transistors included in each switch). The phrase “performing impedance matching by controlling the bias voltage” may include matching the impedance viewed from the input end (e.g., point P and/or Q of FIG. 4) of the rectification circuit 303 to the resonance circuit 301 with the impedance viewed to the rectification circuit 303. For example, the control circuit 311 may perform impedance matching by controlling the impedance of the switches included in the rectification circuit 303 and/or the conduction angle of the switches (e.g., transistors), which is described below in greater detail.

According to various embodiments, the control circuit 311 may control the impedance of the switches included in the rectification circuit 303 based on identifying the phase difference between the voltage V_{AC} and current I_{AC}. For example, the control circuit 311 may control the impedance of the switches included in the rectification circuit 303 by controlling the bias voltage of the switches included in the rectification circuit 303 (e.g., the gate-source voltage V_{gs} of one or more transistors included in each switch). For example, the switches included in the rectification circuit 303 may include two or more transistors (e.g., BJT and/or metal oxide semiconductor field effect transistor (MOSFET) (e.g., N-MOSFET or P-MOSFET)) connected in series and/or parallel. The control circuit 311 may rectify the power (e.g., AC power) provided from the resonance circuit 301 by controlling (e.g., turn on and off) the on/off state of the switches of the rectification circuit 303 and determine the number of at least one transistor to remain in the turn-off state during the rectification process among the transistors included in the switches of the rectification circuit 303. For example, the control circuit 311 may control the driving circuit (e.g., the gate driver) to apply the gate voltage V_{g}, which allows the gate-source voltage V_{gs} to be the driving voltage (e.g., threshold voltage Vₜₕ) or less, to the determined number of transistors, so that the determined number of transistors remain in the turn-off state during the rectification process. Thus, the impedance (in other words, the input impedance of each switch) (e.g., capacitance (e.g., drain-source capacitance C_{ds})) and/or on-resistance (e.g., drain-source on-resistance R_{ds_on})), internal pressure, and/or reaction speed of the switches included in the rectification circuit 303 may be determined based on the number of transistors that remain in the turn-off state during the rectification process.

According to various embodiments, the control circuit 311 may control (e.g., adjust) the conduction angle of the switches (e.g., transistors) based on identifying the phase difference between the voltage V_{AC} and current I_{AC}. For example, the control circuit 311 may control the conduction angle of the switches (e.g., transistors) by controlling the bias voltage of the switches included in the rectification circuit 303 (e.g., the gate-source voltage V_{gs} of one or more transistors included in each switch). For example, the control circuit 311 may control the bias voltage (e.g., the gate-source voltage V_{gs}) of one or more transistors included in the switches included in the rectification circuit 303.

According to the above-described control operation by the control circuit 311, the phase difference between the voltage V_{AC} and current I_{AC} may be reduced (or removed), and a specific method is described below in greater detail with the drawings.

According to an embodiment, the control circuit 311 may also detect the output end voltage V_{RECT} of the rectification circuit 303 and the current I_{RECT} output from the rectification circuit 303 and may control the impedance of the switches included in the rectification circuit 303 or the bias voltage of the switches included in the rectification circuit 303 so that the power output from the rectification circuit 303 is maximized or increased (e.g., the product of the output end voltage V_{RECT} and the current I_{RECT} is maximized or increased).

According to an embodiment, the electronic device 101 may further include an ADC sampler at the output end of the rectification circuit 303. The output end voltage V_{RECT} and current I_{RECT} may include high-order harmonics based on the switching operation of the switches included in the rectification circuit 303. According to various embodiments, the control circuit 311 may sample the output end voltage V_{RECT} and current I_{RECT} using the ADC sampler, identify the phase difference between the voltage V_{RECT} and the current I_{RECT} based on the high-order harmonics included in the voltage V_{RECT} and current I_{RECT}, and control the impedance of the switches in the rectification circuit 303 or bias voltage of the switches included in the rectification circuit 303 so that the phase difference between the voltage V_{RECT} and current I_{RECT} reduces.

According to various embodiments, the control circuit 311 may be implemented as a microprocessor or a micro controlling unit (MCU), but is not limited thereto. According to various embodiments, the control circuit 311 may be implemented to include an analog element.

According to various embodiments, the communication circuit 313 may be implemented as, e.g., a BLE communication circuit, but as long as it is a circuit capable of transmitting/receiving communication signals, there is no limitation in the communication scheme. According to various embodiments, the communication circuit 313 may transmit received power information to the wireless power transmission device 1.

The operations described may be operations performed by the control circuit 311 or operations that control another component (e.g., the rectifier 303) to perform designated operations, unless otherwise specified.

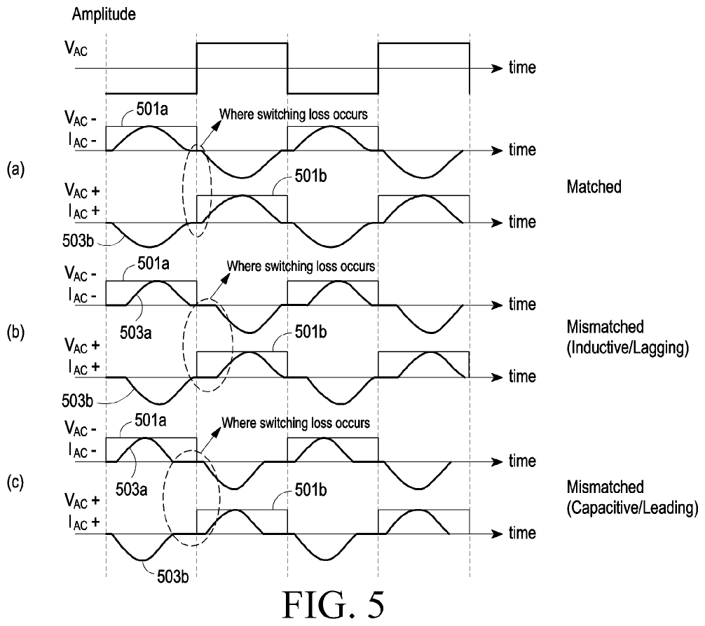

FIG. 4 illustrates loop circuits of a resonance circuit (e.g., the resonance circuit 301 of FIG. 3) and a rectification circuit (e.g., the rectification circuit 303 of FIG. 3) according to various embodiments. FIG. 5 illustrates the waveforms of voltage V_{AC} and current I_{AC} according to various embodiments.

FIG. 4 illustrates a capacitor (e.g., the capacitor 203 of FIG. 2) of the resonance circuit 301 and switches 401a, 401b, 401c, and 401d of the rectification circuit 303. For example, each of the switches 401a, 401b, 401c, and 401d may include one or more transistors. FIG. 4 illustrates a case in which each switch 401a, 401b, 401c or 401d includes a single transistor for convenience of description. According to various embodiments, at least one capacitor 403a or 403b may be disposed between the capacitor 203 and the switches 401a, 401b, 401c, and 401d or may be omitted. According to various embodiments, a capacitor 409 and/or a resistor (not shown) may be disposed at the output end of the rectification circuit 303. According to the switching operations of the switches 401a, 401b, 401c, and 401d, the rectified power may be stored in the capacitor 409 and then transferred to a DC/DC converter (e.g., the DC/DC converter 305 of FIG. 3). Meanwhile, the capacitor 409 may be used as an input capacitor of the DC/DC converter 305. According to various embodiments, the voltage V_{rect} across the capacitor 409 may be the voltage of the power rectified according to the switching operation of the switches 401a, 401b, 401c and 401d. According to various embodiments, the PGND 411 may be a power ground.

According to various embodiments, a loop circuit where the AC current (e.g., the current I_{AC} of FIG. 3) input from the resonance circuit 301 may be formed through the capacitor 203 and the rectification circuit 303 (e.g., the switches 401a, 401b, 401c and 401d). For example, the AC current I_{AC}+ input from the resonance circuit 301 to point P (e.g., flowing to point P) may flow in the path 405 connecting the capacitor 203, the first switch 401a, the capacitor 409, and the fourth switch 401d, based on the first switch 401a and the fourth switch 401d being controlled to an on state (e.g., turned on) and the second switch 401b and the third switch 401c being controlled to an off state (e.g., turned off). For example, the AC current I_{AC}− input from the resonance circuit 301 to point Q (e.g., flowing to point Q) may flow in the path 407 connecting the capacitor 203, the third switch 401c, the capacitor 409, and the second switch 401b, based on the second switch 401b and the third switch 401c being controlled to an on state (e.g., turned on) and the first switch 401a and the fourth switch 401b being controlled to an off state (e.g., turned off).

According to various embodiments, according to the control of the control circuit (e.g., the control circuit 311 of FIG. 3), the switches 401a, 401b, 401c and 401d may be controlled to an on or off state (e.g., switched) at proper timings and, if a difference is present between the phase of the AC current I_{AC}+ or I_{AC}− and the phase of the voltage V_{AC} input from the resonance circuit 301, switching loss may occur. For example, the control circuit may use at least one of the voltage and/or current applied to the resonance circuit 301 as a synchronization signal, but the type of signal to be used as a synchronization signal is not limited.

FIG. 5 illustrates the waveforms (e.g., I_{AC}+ 503b or I_{AC}− 503a and AC voltage V_{AC}+ 501b and V_{AC}− 501a), over time, of the AC current I_{AC}+ or I_{AC}− and AC voltage V_{AC}+ or V_{AC}− input from the resonance circuit 301. In FIG. 5, V_{AC}+ may be the voltage measured at point P of FIG. 4, and V_{AC}− may be the voltage measured at point Q of FIG. 4. In FIG. 5, the vertical axis is the relative magnitude (e.g., current value) of the AC current I_{AC}+ or I_{AC}− or the relative magnitude (e.g., voltage value) of the AC voltage V_{AC}+ or V_{AC}− but does not mean the absolute magnitude of the AC current I_{AC}+ or I_{AC}− or AC voltage V_{AC}+ or V_{AC}−. According to various embodiments, while the switches 401a, 401b, 401c and 401d are turned on or turned off, two paths of loop circuits are formed through the capacitor 203 and the rectification circuit 303 (e.g., the switches 401a, 401b, 401c and 401d), so that the AC voltage V_{AC}+ or V_{AC}− may have a square waveform (e.g., 501a or 501b). Referring to FIG. 5, V_{AC} may be measured as the V_{AC}+ and V_{AC}− waveforms according to the switching operation of the rectification circuit 303.

The phase difference between the AC current I_{AC}+ or I_{AC}− and the AC voltage V_{AC}+ or V_{AC}− may be calculated as the product of the time difference between the rising time of the AC current I_{AC}+ or I_{AC}− and the AC voltage V_{AC}+ or V_{AC}− and the frequency of the AC current I_{AC}+ or I_{AC}− or the AC voltage V_{AC}+ or V_{AC}−. According to various embodiments, the rising time of the AC current I_{AC}+ or I_{AC}− may be identified as a time when the magnitude (e.g., current value) of the AC current I_{AC}+ or I_{AC}− increases or as a time when the magnitude (e.g., current value) of the AC current I_{AC}+ or I_{AC}− is maximized or increased within one interval. According to various embodiments, the rising time of the AC voltage V_{AC}+ or V_{AC}− may be identified as a time when the magnitude (e.g., voltage value) of the AC voltage V_{AC}+ or V_{AC}− increases or as a time when the magnitude (e.g., voltage value) of the AC voltage V_{AC}+ or V_{AC}− is maximized or increased within one interval. If the phase of the AC current I_{AC}+ or I_{AC}− is later than the phase of the AC voltage V_{AC}+ or V_{AC}− (e.g., (b) of FIG. 5), it may be described as an inductive state and/or lagging state. Here, the inductive state is a state in which the inductive reactance is larger than the capacitive reactance. If the phase of the AC current I_{AC}+ or I_{AC}− is earlier than the phase of the AC voltage V_{AC}+ or V_{AC}− (e.g., (c) of FIG. 5), it may be described as a capacitive state and/or leading state. Here, the capacitive state is a state in which the capacitive reactance is larger than the inductive reactance. According to various embodiments, the phase difference between the AC current I_{AC}+ or I_{AC}− and the AC voltage V_{AC}+ or V_{AC}− may be expressed in relation to the conductance angle β when referring to Equations 1 to 3.

$${V}_{AC} ( wt ) = \{ \begin{matrix}0 , & - α \leq wt < ( π - α - β ) \\ - {V}_{0} , & ( π - α - β ) \leq wt < ( π - α ) \\ 0 , & ( π - α ) \leq wt < ( 2 π - α - β ) \\ + {V}_{0} , & ( 2 π - α - β ) \leq wt < ( 2 π - α ) )\end{matrix} \qquad [ Equation 1 ]$$

$${I}_{AC} ( wt ) = {I}_{AC} \cdot sin ( wt + α + β - 2 π ) \qquad [ Equation 2 ]$$

$${Z}_{L , eq} = \frac{4}{{π}^{2}} \cdot {R}_{L} \cdot ( 1 - cos β ) \cdot sin \frac{β}{2} \cdot {e}^{j ( \frac{π}{2} - \frac{β}{2} )} \qquad [ Equation 3 ]$$

In Equation 1, w may be the angular velocity, wt may be the voltage phase, V₀ may be the magnitude of the voltage of the power provided to the rectification circuit 303, and β may be the conduction angle. In Equation 2, I_{AC} may be the amplitude of the current of power provided to the rectification circuit 303. In Equation 3, Z_{L,eq} may be the input impedance when viewed to the input end of the rectification circuit 303, and R_{L} may be the load resistance of the electronic device 101. The phase difference between the AC current I_{AC}+ or I_{AC}− and the AC voltage V_{AC}+ or V_{AC}− may be

$$( \frac{π}{2} - \frac{β}{2} )$$

of Equation 3 and may be related to the conduction angle β. If

$$( \frac{π}{2} - \frac{β}{2} )$$

is positive, the phase of the AC current I_{AC}+ or I_{AC}− may be described as being in the lagging state and, if

$$( \frac{π}{2} - \frac{β}{2} )$$

is negative, the phase of the AC current I_{AC}+ or I_{AC}− may be described as being in the leading state.

Meanwhile, in another embodiment, the electronic device 101 may perform the operations performed based on the phase values according to various embodiments, based on the times of the AC current I_{AC}+ or I_{AC}− and the AC voltage V_{AC}+ or V_{AC}−, instead of the above-described phase values.

According to various embodiments, if the coupling coefficient and/or mutual inductance (e.g., M of FIG. 2B) between the wireless power transmission device (e.g., the wireless power transmission device 1 of FIG. 2A) and the electronic device (e.g., the electronic device 101 of FIG. 1) varies while the switches 401a, 401b, 401c and 401d are turned on and off at the timings set for rectification and the AC power input from the resonance circuit 301 is rectified (e.g., (a) of FIG. 5), a phase difference may occur between the AC current I_{AC}+ or I_{AC}− and the AC voltage V_{AC}+ or V_{AC}− as shown in (b) or (c) of FIG. 5. Meanwhile, although the switches 401a, 401b, 401c and 401d are turned on and off at the timings set for rectification so that the AC power input from the resonance circuit 301 is rectified, a phase difference may occur between the AC current I_{AC}+ or I_{AC}− and the AC voltage V_{AC}+ or V_{AC}− due to a phase delay caused by the internal impedance (e.g., the drain-source on-resistance R_{ds_on} and/or the drain-source capacitance C_{ds}) of the transistor of each switches 401a, 401b, 401c or 401d. Such a phase difference may cause a decrease (e.g., switching loss) in the efficiency (e.g., power conversion efficiency) of the power which is converted according to the on/off control (e.g., switching) of the switches 401a, 401b, 401c and 401d and transferred to the DC/DC converter 305.

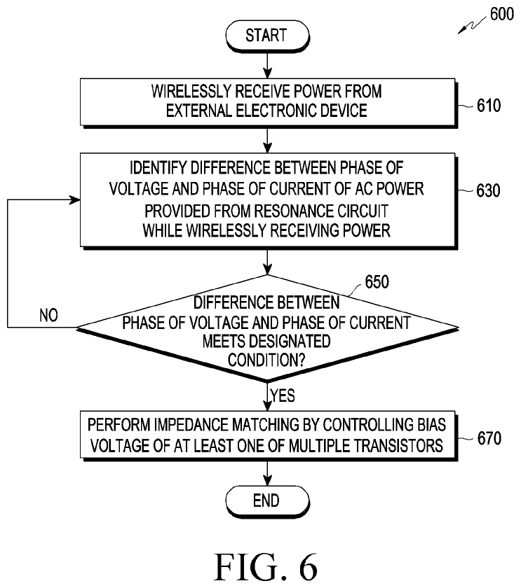

FIG. 6 is a flowchart 600 illustrating a method for controlling a rectification circuit 303 based on a phase difference between a voltage (e.g., V_{AC} of FIG. 3) and current (e.g., I_{AC} of FIG. 3) input to a rectification circuit (e.g., the rectification circuit 303 of FIG. 3) by an electronic device (e.g., the electronic device 101 of FIG. 1) according to various embodiments.

According to various embodiments, in operation 610, the electronic device 101 may wirelessly receive power from an external electronic device (e.g., the wireless power transmission device 1 of FIG. 2A). For example, the electronic device 101 may wirelessly receive power from the external electronic device (e.g., the wireless power transmission device 1) according to a resonance scheme, an electromagnetic wave scheme, and/or an induction scheme.

According to various embodiments, in operation 630, the electronic device 101 may identify a difference between the phase of the voltage V_{AC} and the phase of the current I_{AC} of the AC power provided from the resonance circuit (e.g., the resonance circuit 301 of FIG. 3) while wirelessly receiving power. For example, the electronic device 101 may identify the phase difference between the voltage V_{AC} and current I_{AC} measured between the resonance circuit 301 and the rectifier 303 (e.g., point P and/or Q of FIG. 4). More specifically, the electronic device 101 may identify the phase difference between the current I_{AC}+ and the voltage V_{AC}+ and/or the phase difference between the current I_{AC}− and the voltage V_{AC}−.

According to various embodiments, in operation 650, the electronic device 101 may identify whether the difference between the phase of the voltage V_{AC} and the phase of the current I_{AC} meets a designated condition. For example, the designated condition may indicate that the difference between the phase of the voltage V_{AC} and the phase of the current I_{AC} exceeds a threshold magnitude. As another example, the designated condition may indicate identifying that the difference between the phase of the voltage V_{AC} and the phase of the current I_{AC} exceeds the threshold magnitude, a designated number of times or more.

According to various embodiments, upon identifying that the difference between the phase of the voltage V_{AC} and the phase of the current I_{AC} meets the designated condition, the electronic device 101 may perform impedance matching by controlling the bias voltage of at least one of the plurality of transistors in operation 670.

According to various embodiments, the rectification circuit 303 may include a plurality of switches (e.g., the first switch 401a, the second switch 401b, the third switch 401c, and/or the fourth switch 401d of FIG. 4) constituting a bridge circuit, and each of the plurality of switches (e.g., the first switch 401a, the second switch 401b, the third switch 401c, and/or the fourth switch 401d of FIG. 4) may include two or more transistors. According to various embodiments, the electronic device 101 may control the bias voltage applied to the at least one transistor (e.g., apply a gate voltage Vg to allow the magnitude of the gate-source voltage V_{gs} to be equal to or lower than the driving voltage (e.g., the threshold voltage Vₜₕ)) so that at least one transistor among the plurality of transistors included in the plurality of switches (e.g., the first switch 401a, the second switch 401b, the third switch 401c, and/or the fourth switch 401d of FIG. 4) remains in a turn-off state. According to various embodiments, the electronic device 101 may adjust the impedance (e.g., input impedance) of at least one of the plurality of switches by allowing at least one transistor among the plurality of transistors included in the plurality of switches (e.g., the first switch 401a, the second switch 401b, the third switch 401c, and/or the fourth switch 401d of FIG. 4) to remain in a turn-off state. According to various embodiments, the difference (or switching loss) between the phase of the voltage V_{AC} and the phase of the current I_{AC} may be controlled (e.g., reduced) based on adjustment of the impedance (e.g., input impedance) of at least one switch among the plurality of switches.

According to various embodiments, the electronic device 101 may control the magnitude of the bias voltage (e.g., the gate-source voltage Vgs) applied to at least one of the plurality of switches (e.g., the first switch 401a, the second switch 401b, the third switch 401c, and/or the fourth switch 401d of FIG. 4) (e.g., applied to one or more transistors included in at least one switch). According to various embodiments, the turn-on or turn-off timing of at least one switching element may be adjusted based on control of the magnitude of the bias voltage applied to the at least one switching element. According to various embodiments, the difference (or switching loss) between the phase of the voltage V_{AC} and the phase of the current I_{AC} may be controlled (e.g., reduced) based on adjustment of the turn-on or turn-off timing of the at least one switching element. According to various embodiments, the conduction angle β may be adjusted based on control of the magnitude of the bias voltage applied to at least one switching element. As the conduction angle β is adjusted, the difference (e.g.,

$$( \frac{π}{2} - \frac{β}{2} ) \begin{matrix} \\ )\end{matrix}$$

between the phase of the voltage V_{AC} and the phase of the current I_{AC} may be controlled (e.g., reduced).

According to various embodiments, upon identifying that the difference between the phase of the voltage V_{AC} and the phase of the current I_{AC} does not meet the designated condition, the electronic device 101 may perform operation 630 again. For example, upon identifying that the difference between the phase of the voltage V_{AC} and the phase of the current I_{AC} does not meet the designated condition, the electronic device 101 may again measure the phases of the voltage V_{AC} and current I_{AC} of the AC power provided from the resonance circuit 301 to identify the phase difference between the voltage V_{AC} and current I_{AC}.

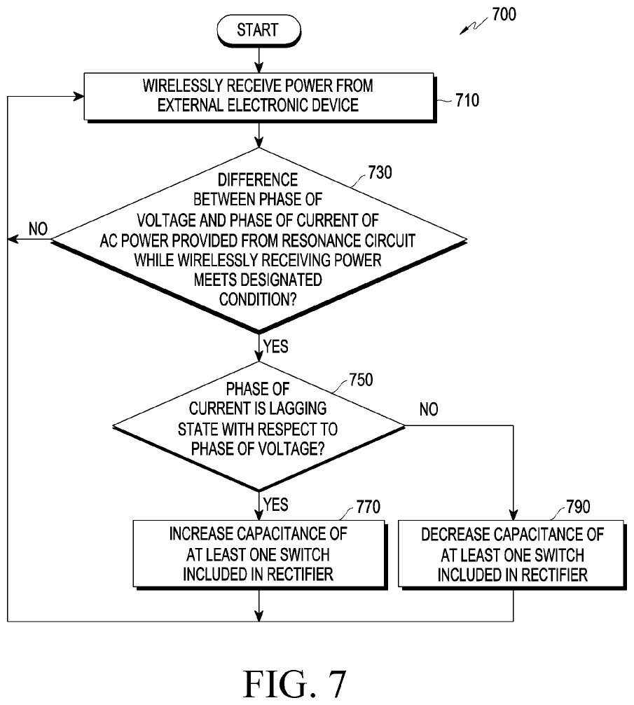

FIG. 7 is a flowchart 700 illustrating a method for controlling the impedance of a rectification circuit (e.g., the rectification circuit 303 of FIG. 3) based on a phase difference between a voltage (e.g., V_{AC} of FIG. 3) and current (e.g., I_{AC} of FIG. 3) by an electronic device (e.g., the electronic device 101 of FIG. 1) according to various embodiments.

According to various embodiments, in operation 710, the electronic device 101 may wirelessly receive power from an external electronic device (e.g., the wireless power transmission device 1 of FIG. 2A).

According to various embodiments, in operation 730, the electronic device 101 may identify a difference between the phase of the voltage V_{AC} and the phase of the current I_{AC} of the AC power provided from the resonance circuit (e.g., the resonance circuit 301 of FIG. 3) while wirelessly receiving power.

According to various embodiments, in operation 750, the electronic device 101 may identify whether the difference between the phase of the voltage V_{AC} and the phase of the current I_{AC} meets a designated condition. According to various embodiments, upon identifying that the difference between the phase of the voltage V_{AC} and the phase of the current I_{AC} meets the designated condition, the electronic device 101 may increase (e.g., operation 770) or reduce (e.g., operation 790) the input impedance of the rectification circuit 303. According to various embodiments, upon identifying that the difference between the phase of the voltage V_{AC} and the phase of the current I_{AC} does not meet the designated condition, the electronic device 101 may perform operation 710 again. For example, upon identifying that the difference between the phase of the voltage V_{AC} and the phase of the current I_{AC} does not meet the designated condition, the electronic device 101 may maintain the impedance (e.g., input impedance) of the rectification circuit 303 (e.g., maintain the capacitance of the switches included in the rectification circuit 303).

According to various embodiments, upon identifying that the difference between the phase of the voltage V_{AC} and the phase of the current I_{AC} meets the designated condition, the electronic device 101 may identify whether the phase of the current I_{AC} is in a lagging state with respect to the phase of the voltage V_{AC} in operation 750. According to various embodiments, upon identifying that the phase of the current I_{AC}+ lags the phase of the voltage V_{AC}+ and/or the phase of the current I_{AC}− lags the phase of the voltage V_{AC}−, the electronic device 101 may identify that it is in the lagging state. According to various embodiments, upon identifying that the phase of the current I_{AC}+ leads the phase of the voltage V_{AC}+ and/or the phase of the current I_{AC}− leads the phase of the voltage V_{AC}−, the electronic device 101 may identify that it is not in the lagging state (e.g., it is in the leading state).

According to various embodiments, upon identifying that the phase of the current I_{AC} is in the lagging state with respect to the phase of the voltage V_{AC}, the electronic device 101 may increase the capacitance of at least one switch included in the rectification circuit 303 in operation 770.

According to various embodiments, upon identifying that the phase of the current I_{AC} is not in the lagging state with respect to the phase of the voltage V_{AC}, the electronic device 101 may reduce the capacitance of at least one switch included in the rectification circuit 303 in operation 790.

According to various embodiments, the electronic device 101 may perform operation 710 again after performing operation 770 and/or 790.

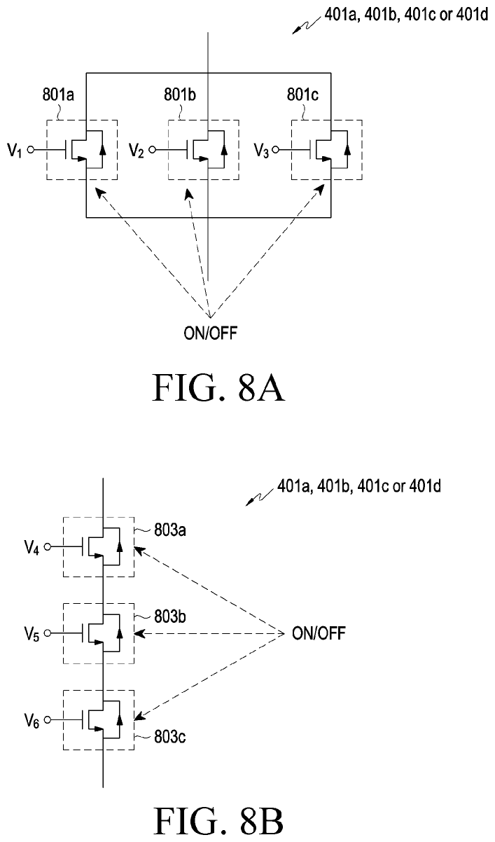

FIG. 8A illustrates an example of transistors included in each of a plurality of switches (e.g., the first switch 401a, the second switch 401b, the third switch 401c, and/or the fourth switch 401d of FIG. 4) constituting a rectification circuit (e.g., the rectification circuit 303 of FIG. 3) according to various embodiments. FIG. 8B illustrates another example of transistors included in each of a plurality of switches (e.g., the first switch 401a, the second switch 401b, the third switch 401c, and/or the fourth switch 401d) constituting a rectification circuit 303 according to various embodiments.

According to various embodiments, each of the plurality of switches (e.g., the first switch 401a, the second switch 401b, the third switch 401c, and/or the fourth switch 401d of FIG. 4) constituting the rectification circuit 303 may include two or more transistors. FIG. 8A and/or FIG. 8B illustrates any one of the plurality of switches (e.g., the first switch 401a, the second switch 401b, the third switch 401c, and/or the fourth switch 401d).

Referring to FIG. 8A, the switches (e.g., the first switch 401a, the second switch 401b, the third switch 401c, and/or the fourth switch 401d) may include two or more transistors 801a, 801b, and 801c connected in parallel to each other. For example, the included transistors may include BJTs and/or MOSFETs (e.g., N-MOSFETs or P-MOSFETs). According to various embodiments, gate voltages Vg (e.g., V1, V2, and V3) may be applied to the gates of the transistors 801a, 801b, and 801c, respectively. According to various embodiments, the transistors 801a, 801b, and 801c may be turned on when the magnitude of the gate-source voltage V_{gs} exceeds the magnitude of the driving voltage (e.g., threshold voltage Vₜₕ) and be turned off when the magnitude of the gate-source voltage V_{gs} is equal to or less than the driving voltage (e.g., threshold voltage Vₜₕ). According to various embodiments, if the gate voltage Vg to allow the magnitude of the gate-source voltage V_{gs} to be the driving voltage (e.g., threshold voltage Vₜₕ) or less is applied to the transistor, the transistor may be turned off and remain in the turn-off state during the rectification process of the rectification circuit 303 (e.g., while the switching element is turned off and turned on so that AC power is rectified into DC power). According to various embodiments, the capacitance (e.g., the sum of the drain-source capacitances C_{ds} of the other transistors than the transistor remaining in the turn-off state, included in the switch) of the switch (e.g., the first switch 401a, the second switch 401b, the third switch 401c, or the fourth switch 401d) may be varied based on at least one of the transistors 801a, 801b, and 801c remaining in the turn-off state during the rectification process of the rectification circuit 303. For example, as the number of transistors remaining in the turn-off state during the rectification process of the rectification circuit 303 increases, the capacitance of the switch (e.g., the first switch 401a, the second switch 401b, the third switch 401c, or the fourth switch 401d) may reduce, so that the input impedance (e.g., drain-source on-resistance R_{ds_on}) of the switch (e.g., the first switch 401a, the second switch 401b, the third switch 401c, or the fourth switch 401d) may increase. For example, as the number of transistors remaining in the turn-off state during the rectification process of the rectification circuit 303 decreases, the capacitance of the switch (e.g., the first switch 401a, the second switch 401b, the third switch 401c, or the fourth switch 401d) may increase, so that the input impedance (e.g., drain-source on-resistance R_{ds_on}) of the switch (e.g., the first switch 401a, the second switch 401b, the third switch 401c, or the fourth switch 401d) may decrease. According to various embodiments, upon identifying that the phase of the current I_{AC} is in the lagging state with respect to the phase of the voltage V_{AC}, the electronic device 101 may reduce the number of transistors remaining in the turn-off state during the rectification process to increase the capacitance of the switch (e.g., the first switch 401a, the second switch 401b, the third switch 401c, or the fourth switch 401d) (e.g., operation 770). Referring to FIG. 5, the phase of the current I_{AC} may be controlled to be earlier based on the increase in the capacitance of the switch, so that the difference between the phase of the voltage V_{AC} and the phase of the current I_{AC} may reduce (e.g., (b)→(a) of FIG. 5). According to various embodiments, upon identifying that the phase of the current I_{AC} is in the leading state with respect to the phase of the voltage V_{AC}, the electronic device 101 may increase the number of transistors remaining in the turn-off state during the rectification process, reducing the capacitance of the switch (e.g., the first switch 401a, the second switch 401b, the third switch 401c, or the fourth switch 401d) (e.g., operation 790). Referring to FIG. 5, the phase of the current I_{AC} may be controlled to be later based on the decrease in the capacitance of the switch, so that the difference between the phase of the voltage V_{AC} and the phase of the current I_{AC} may reduce (e.g., (c)→(a) of FIG. 5).

Referring to FIG. 8B, the switches (e.g., the first switch 401a, the second switch 401b, the third switch 401c, and/or the fourth switch 401d) may include two or more transistors 803a, 803b, and 803c connected in series to each other. For example, the included transistors may include BJTs and/or MOSFETs (e.g., N-MOSFETs or P-MOSFETs). According to various embodiments, gate voltages Vg (e.g., V4, V5, and V6) may be applied to the gates of the transistors 803a, 803b, and 803c, respectively. According to various embodiments, the transistors 803a, 803b, and 803c may be turned on when the magnitude of the gate-source voltage V_{gs} exceeds the magnitude of the driving voltage (e.g., threshold voltage Vₜₕ) and be turned off when the magnitude of the gate-source voltage V_{GS} is equal to or less than the driving voltage (e.g., threshold voltage Vₜₕ). According to various embodiments, if the gate voltage Vg to allow the magnitude of the gate-source voltage V_{gs} to be the driving voltage (e.g., threshold voltage Vₜₕ) or less is applied to the transistor, the transistor may be turned off and remain in the turn-off state during the rectification process of the rectification circuit 303 (e.g., while the switching element is turned off and turned on so that AC power is rectified into DC power). According to various embodiments, the capacitance (e.g., the reciprocal of the sum of the reciprocals of the drain-source capacitances C_{ds} of the other transistors than the transistor remaining in the turn-off state, included in the switch) of the switch (e.g., the first switch 401a, the second switch 401b, the third switch 401c, or the fourth switch 401d) may be varied based on at least one of the transistors 803a, 803b, and 803c remaining in the turn-off state during the rectification process of the rectification circuit 303. For example, as the number of transistors remaining in the turn-off state during the rectification process of the rectification circuit 303 increases, the capacitance of the switch (e.g., the first switch 401a, the second switch 401b, the third switch 401c, or the fourth switch 401d) may increase, so that the input impedance (e.g., drain-source on-resistance R_{ds_on}) of the switch (e.g., the first switch 401a, the second switch 401b, the third switch 401c, or the fourth switch 401d) may decrease. For example, as the number of transistors remaining in the turn-off state during the rectification process of the rectification circuit 303 decreases, the capacitance of the switch (e.g., the first switch 401a, the second switch 401b, the third switch 401c, or the fourth switch 401d) may decrease, so that the input impedance (e.g., drain-source on-resistance R_{ds_on}) of the switch (e.g., the first switch 401a, the second switch 401b, the third switch 401c, or the fourth switch 401d) may increase. According to various embodiments, upon identifying that the phase of the current I_{AC} is in the lagging state with respect to the phase of the voltage V_{AC}, the electronic device 101 may increase the number of transistors remaining in the turn-off state during the rectification process to increase the capacitance of the switch (e.g., the first switch 401a, the second switch 401b, the third switch 401c, or the fourth switch 401d) (e.g., operation 770). Referring to FIG. 5, the phase of the current I_{AC} may be controlled to be earlier based on the increase in the capacitance of the switch, so that the difference between the phase of the voltage V_{AC} and the phase of the current I_{AC} may reduce (e.g., (b)→(a) of FIG. 5). According to various embodiments, upon identifying that the phase of the current I_{AC} is in the leading state with respect to the phase of the voltage V_{AC}, the electronic device 101 may decrease the number of transistors remaining in the turn-off state during the rectification process, reducing the capacitance of the switch (e.g., the first switch 401a, the second switch 401b, the third switch 401c, or the fourth switch 401d) (e.g., operation 790). Referring to FIG. 5, the phase of the current I_{AC} may be controlled to be later based on the decrease in the capacitance of the switch, so that the difference between the phase of the voltage V_{AC} and the phase of the current I_{AC} may reduce (e.g., (c)→(a) of FIG. 5).

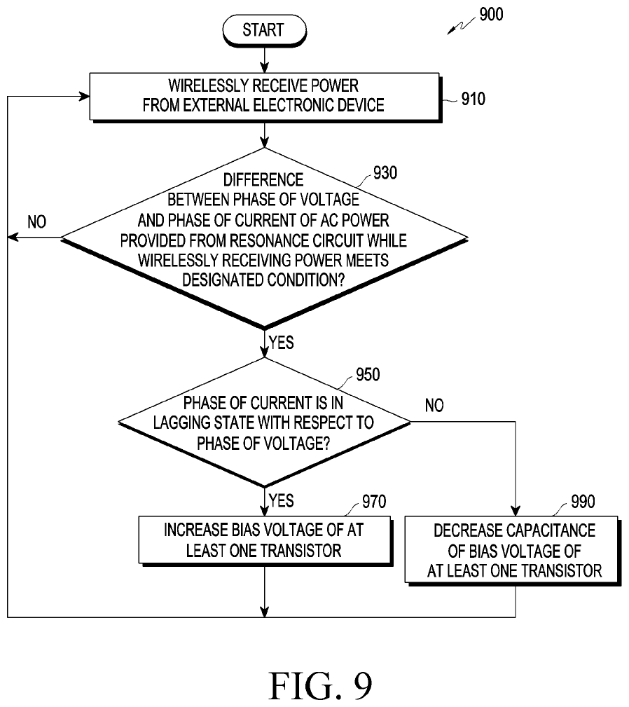

FIG. 9 is a flowchart 900 illustrating a method for controlling the bias voltage of transistors included in a rectification circuit (e.g., the rectification circuit 303 of FIG. 3) based on a phase difference between a voltage (e.g., V_{AC} of FIG. 3) and current (e.g., I_{AC} of FIG. 3) by an electronic device (e.g., the electronic device 101 of FIG. 1) according to various embodiments.

According to various embodiments, in operation 910, the electronic device 101 may wirelessly receive power from an external electronic device (e.g., the wireless power transmission device 1 of FIG. 2A).

According to various embodiments, in operation 930, the electronic device 101 may identify a difference between the phase of the voltage V_{AC} and the phase of the current I_{AC} of the AC power provided from the resonance circuit (e.g., the resonance circuit 301 of FIG. 3) while wirelessly receiving power.

According to various embodiments, in operation 950, the electronic device 101 may identify whether the difference between the phase of the voltage V_{AC} and the phase of the current I_{AC} meets a designated condition. According to various embodiments, upon identifying that the difference between the phase of the voltage V_{AC} and the phase of the current I_{AC} meets the designated condition, the electronic device 101 may increase (e.g., operation 970) or reduce (e.g., operation 990) the bias voltage of the transistors included in the rectification circuit 303. For example, the rectification circuit 303 may include a plurality of switches constituting a bridge circuit, and each switch may include one or more transistors. The electronic device 101 may control the bias voltage (e.g., the gate-source voltage V_{gs}) applied to one or more transistors included in each switch. According to various embodiments, upon identifying that the difference between the phase of the voltage V_{AC} and the phase of the current I_{AC} does not meet the designated condition, the electronic device 101 may perform operation 910 again. For example, upon identifying that the difference between the phase of the voltage V_{AC} and the phase of the current I_{AC} does not meet the designated condition, the electronic device 101 may maintain the magnitude of the bias voltage (e.g., gate-source voltage V_{gs}) applied to the one or more transistors included in each switch constituting the bridge circuit.

According to various embodiments, upon identifying that the difference between the phase of the voltage V_{AC} and the phase of the current I_{AC} meets the designated condition, the electronic device 101 may identify whether the phase of the current I_{AC} is in a lagging state with respect to the phase of the voltage V_{AC} in operation 950. According to various embodiments, upon identifying that the phase of the current I_{AC}+ lags the phase of the voltage V_{AC}+ and/or the phase of the current I_{AC}− lags the phase of the voltage V_{AC}−, the electronic device 101 may identify that it is in the lagging state. According to various embodiments, upon identifying that the phase of the current I_{AC}− leads the phase of the voltage V_{AC}+ and/or the phase of the current I_{AC}− leads the phase of the voltage V_{AC}−, the electronic device 101 may identify that it is not in the lagging state (e.g., it is in the leading state).

According to various embodiments, upon identifying that the phase of the current I_{AC} is in the lagging state with respect to the phase of the voltage V_{AC}, the electronic device 101 may increase the bias voltage of at least one transistor in operation 970. For example, the electronic device 101 may increase the magnitude of the bias voltage (e.g., gate-source voltage V_{gs}) applied to one or more transistors included in each switch constituting the bridge circuit. For example, the electronic device 101 may increase the bias voltage (e.g., gate-source voltage V_{gs}) applied to one or more transistors by a predetermined magnitude (e.g., 0.1V). More specifically, the electronic device 101 may identify (e.g., operation 930) whether the difference between the phase of the voltage V_{AC} and the phase of the current I_{AC} meets the designated condition again after increasing the bias voltage (e.g., gate-source voltage V_{gs}) applied to one or more transistors by the predetermined magnitude (e.g., 0.1V) and, if the difference between the phase of the voltage V_{AC} and the phase of the current I_{AC} is identified to meet the designated condition, perform the operation of increasing the bias voltage (e.g., gate-source voltage V_{gs}) by the predetermined magnitude (e.g., 0.1V) again, thereby increasing the magnitude of the bias voltage (e.g., gate-source voltage V_{gs}) until the difference between the phase of the voltage V_{AC} and the phase of the current I_{AC} meets the designated condition. Accordingly, the magnitude of the bias voltage (e.g., gate-source voltage V_{gs}) may gradually increase. According to various embodiments, since the timing (in other words, switching timing) when the magnitude of the gate-source voltage V_{gs} exceeds the magnitude of the driving voltage (e.g., threshold voltage Vₜₕ) while the power is provided from the resonance circuit 301 to the rectifier 303 based on the increase in the magnitude (e.g., magnitude of DC voltage) of the bias voltage (e.g., gate-source voltage V_{gs}) applied to one or more transistors is earlier, the turn-on and turn-off timings of the plurality of switches constituting the bridge circuit may be earlier. Thus, the phase of the current I_{AC} may be controlled to be earlier, so that the difference between the phase of the voltage V_{AC} and the phase of the current I_{AC} may reduce (e.g., (b)→(a) of FIG. 5).

According to various embodiments, upon identifying that the phase of the current I_{AC} is not in the leading state with respect to the phase of the voltage V_{AC}, the electronic device 101 may decrease the bias voltage of at least one transistor in operation 990. For example, the electronic device 101 may decrease the magnitude of the bias voltage (e.g., gate-source voltage V_{gs}) applied to one or more transistors included in each switch constituting the bridge circuit. For example, the electronic device 101 may decrease the bias voltage (e.g., gate-source voltage V_{gs}) applied to one or more transistors by a predetermined magnitude (e.g., 0.1V). More specifically, the electronic device 101 may identify (e.g., operation 930) whether the difference between the phase of the voltage V_{AC} and the phase of the current I_{AC} meets the designated condition again after decreasing the bias voltage (e.g., gate-source voltage V_{gs}) applied to one or more transistors by the predetermined magnitude (e.g., 0.1V) and, if the difference between the phase of the voltage V_{AC} and the phase of the current I_{AC} is identified to meet the designated condition, perform the operation of decreasing the bias voltage (e.g., gate-source voltage V_{gs}) by the predetermined magnitude (e.g., 0.1V) again, thereby decreasing the magnitude of the bias voltage (e.g., gate-source voltage V_{gs}) until the difference between the phase of the voltage V_{AC} and the phase of the current I_{AC} meets the designated condition. According to various embodiments, since the timing (in other words, switching timing) when the magnitude of the gate-source voltage V_{gs} exceeds the magnitude of the driving voltage (e.g., threshold voltage Vₜₕ) while the power is provided from the resonance circuit 301 to the rectifier 303 based on the decrease in the magnitude (e.g., magnitude of DC voltage) of the bias voltage (e.g., gate-source voltage V_{gs}) applied to one or more transistors is later, the turn-on and turn-off timings of the plurality of switches constituting the bridge circuit may be later. Thus, the phase of the current I_{AC} may be controlled to be later, so that the difference between the phase of the voltage V_{AC} and the phase of the current I_{AC} may reduce (e.g., (c)→(a) of FIG. 5).

According to various embodiments, the electronic device 101 may perform operation 910 again after performing operation 970 and/or 990.

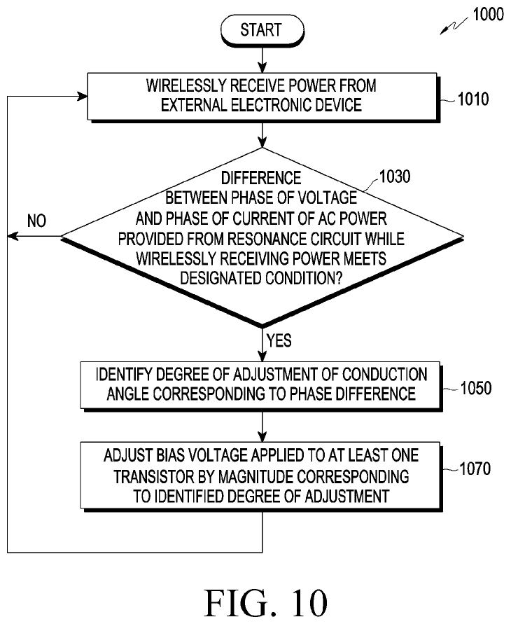

FIG. 10 is a flowchart 1000 illustrating a method for controlling the bias voltage of transistors included in a rectification circuit (e.g., the rectification circuit 303 of FIG. 3) based on a phase difference between a voltage (e.g., V_{AC} of FIG. 3) and current (e.g., I_{AC} of FIG. 3) by an electronic device (e.g., the electronic device 101 of FIG. 1) according to various embodiments.

According to various embodiments, in operation 1010, the electronic device 101 may wirelessly receive power from an external electronic device (e.g., the wireless power transmission device 1 of FIG. 2A).

According to various embodiments, in operation 1030, the electronic device 101 may identify whether a difference between the phase of the voltage V_{AC} and the phase of the current I_{AC} of the AC power provided from the resonance circuit (e.g., the resonance circuit 301 of FIG. 3) while wirelessly receiving power meets a designated condition. According to various embodiments, upon identifying that the difference between the phase of the voltage V_{AC} and the phase of the current I_{AC} does not meet the designated condition, the electronic device 101 may perform operation 1010 again.

According to various embodiments, upon identifying that the difference between the phase of the voltage V_{AC} and the phase of the current I_{AC} meets the designated condition, the electronic device 101 may identify the degree of adjustment of the conduction angle corresponding to the phase difference in operation 1050. According to various embodiments, the degree of adjustment of the conduction angle may indicate the degree (e.g., variation) to which the conduction angle of the current I_{AC} is to be adjusted to allow the phase difference to become a predetermined magnitude (e.g., 0). For example, information (e.g., mapping table) indicating the relationship between phase difference and degree of adjustment of conduction angle may be previously stored in the memory (e.g., the memory 130 of FIG. 1) of the electronic device 101.

TABLE 1

| Phase | Degree of adjustment |
|---|---|
| difference | of conduction angle |
| P_{d} < −π/2 | +π/4 |
| −π/2 ≤ P_{d} < −π/4 | +π/8 |
| −π/4 ≤ P_{d} < −π/8 | +π/16 |
| π/8 ≤ P_{d} < π/4 | −π/16 |
| π/4 ≤ P_{d} < π/2 | −π/8 |
| π/2 ≤ P_{d} | −π/4 |
| Otherwise | 0 |

For example, referring to Table 1, if the phase difference P_{d} falls within a first range (P_{d}<−π/2), the degree of adjustment may be determined to be a first value (+π/4). If the phase difference P_{d} falls within a second range (−π/2≤P_{d}<−π/4), the degree of adjustment may be determined to be a second value (+π/8). If the phase difference P_{d} falls within a third range (−π/4≤P_{d}<−π/8), the degree of adjustment may be determined to be a third value (+π/8). If the phase difference P_{d} falls within a fourth range (π/8≤P_{d}<π/4), the degree of adjustment may be determined to be a fourth value (−π/16). If the phase difference P_{d} falls within a fifth range (π/4≤P_{d}<π/2), the degree of adjustment may be determined to be a fifth value (−π/8). If the phase difference P_{d} falls within a sixth range (π/2≤P_{d}), the degree of adjustment may be determined to be a sixth value (+π/4). If the phase difference P_{d} falls within a seventh range (−π8≤P_{d}<π/8), the degree of adjustment may be determined to be a seventh value (0). According to various embodiments, in operation 1070, the electronic device 101 may adjust the bias voltage (e.g., gate-source voltage V_{gs}) applied to at least one transistor by the magnitude corresponding to the identified degree of adjustment. For example, the electronic device 101 may adjust the bias voltage (e.g., gate-source voltage V_{gs}) applied to one or more transistors included in each switch by the magnitude corresponding to the identified degree of adjustment. For example, if the phase of the current I_{AC} is in the lagging state with respect to the phase of the voltage V_{AC}, the electronic device 101 may increase the bias voltage (e.g., gate-source voltage V_{gs}) applied to one or more transistors by the magnitude corresponding to the identified degree of adjustment (e.g., any one of the fourth range to the sixth range). For example, if the phase of the current I_{AC} is in the leading state with respect to the phase of the voltage V_{AC}, the electronic device 101 may decrease the bias voltage (e.g., gate-source voltage V_{gs}) applied to one or more transistors by the magnitude corresponding to the identified degree of adjustment (e.g., any one of the first range to the third range).

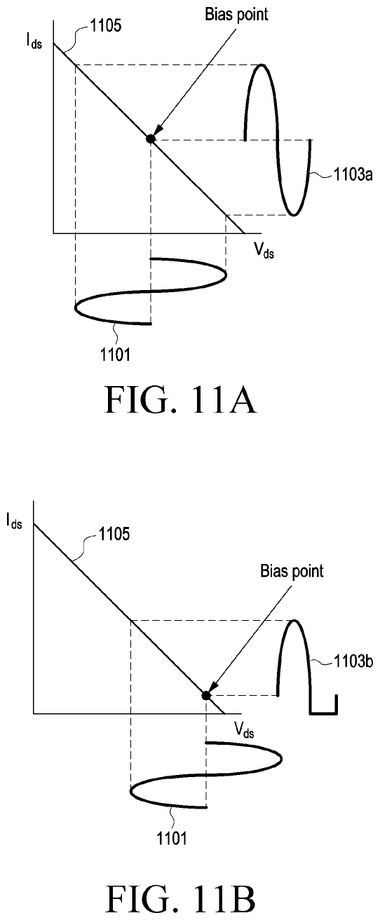

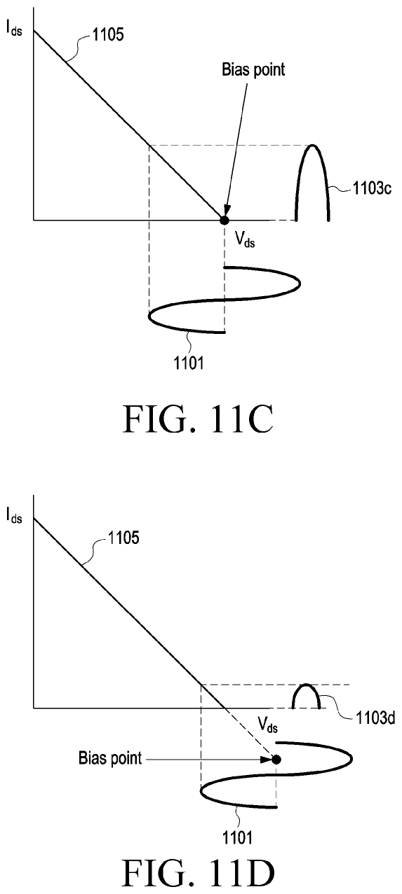

FIG. 11A is a view illustrating a conduction angle when a bias voltage (e.g., gate-source voltage V_{gs}) has a first magnitude according to various embodiments. FIG. 11B is a view illustrating a conduction angle when a bias voltage (e.g., gate-source voltage V_{gs}) has a second magnitude according to various embodiments. FIG. 11C is a view illustrating a conduction angle when a bias voltage (e.g., gate-source voltage V_{gs}) has a third magnitude according to various embodiments. FIG. 11D is a view illustrating a conduction angle when a bias voltage (e.g., gate-source voltage V_{gs}) has a fourth magnitude according to various embodiments. A method for adjusting the conduction angle of a transistor by adjusting the bias voltage (e.g., gate-source voltage V_{gs}) by an electronic device (e.g., the electronic device 101 of FIG. 1) is described below with reference to FIGS. 11A to 11D.

In FIGS. 11A to 11D, the horizontal axis is the drain-source voltage V_{ds} of the transistor, and the vertical axis is the drain-source current I_{ds} of the transistor. Reference number 1101 is the waveform of the drain-source voltage V_{ds} applied (e.g., input) to the transistor based on the power provided from the resonance circuit (e.g., the resonance circuit 301 of FIG. 3), and reference numbers 1103a to 1103d are the waveforms of the drain-source current I_{ds} flowing through the transistor (e.g., output from the transistor) based on the power provided from the resonance circuit (e.g., the resonance circuit 301 of FIG. 3). Reference number 1105 may be the load line of the transistor and may have a slope of −1/R_{ds_on}. “Bias point” is the operating point (e.g., quiescent point) of the transistor and may be determined by the bias voltage (e.g., gate-source voltage V_{gs}) applied to the transistor. For example, “bias point” may be in an upper position of the load curve as the bias voltage (e.g., gate-source voltage V_{gs}) is higher and be in a lower position of the load curve as the bias voltage (e.g., gate-source voltage V_{gs}) is lower.

Referring to FIGS. 11A to 11D, the drain-source current I_{ds} may be output from the transistor in the waveform as indicated by reference numbers 1103a to 1103d within a range exceeding 0 with respect to the operating point (e.g., bias point) of the transistor based on the applied drain-source voltage V_{ds}.

FIG. 11A illustrates the waveform 1103a of the drain-source current I_{ds} when the bias voltage (e.g., gate-source voltage V_{gs}) has a first magnitude. In this case, the conduction angle of the drain-source current I_{ds} is 2π(=360°). FIG. 11B illustrates the waveform 1103b of the drain-source current I_{ds} when the bias voltage (e.g., gate-source voltage V_{gs}) has a second magnitude smaller than the first magnitude. In this case, the conduction angle of the drain-source current I_{ds} may fall within a range from π (=180°) to 2π(=360°). FIG. 11C illustrates the waveform 1103c of the drain-source current I_{ds} when the bias voltage (e.g., gate-source voltage V_{gs}) has a third magnitude smaller than the second magnitude. In this case, the conduction angle of the drain-source current I_{ds} is π (=180°). FIG. 11D illustrates the waveform 1103d of the drain-source current I_{ds} when the bias voltage (e.g., gate-source voltage V_{gs}) has a fourth magnitude smaller than the third magnitude. In this case, the conduction angle of the drain-source current I_{ds} may fall within a range from 0 to π (=180°).

According to various embodiments, as the bias voltage (e.g., gate-source voltage V_{gs}) applied to the transistor gradually increases (e.g., first magnitude→second magnitude→third magnitude→fourth magnitude), the conduction angle of the transistor may decrease. According to various embodiments, as the bias voltage (e.g., gate-source voltage V_{gs}) applied to the transistor gradually decreases (e.g., fourth magnitude→third magnitude→second magnitude→first magnitude), the conduction angle of the transistor may increase.

According to various embodiments, as the conduction angle of the transistor increases, the phase of the current (e.g., I_{AC}) relative to the voltage (e.g., V_{AC}) may increase (e.g., lagging→leading) and, as the conduction angle of the transistor decreases, the phase of the current (e.g., I_{AC}) relative to the voltage (e.g., V_{AC}) may decrease (e.g., leading→lagging). For example, referring back to Equations 1 to 3, the phase difference between the voltage V_{AC} and current I_{AC} may be related to the conduction angle β. When the phase difference

$$( \frac{π}{2} - \frac{β}{2} )$$

is a positive value (e.g., lagging state), as the conduction angle β increases, the phase difference may decrease (e.g., the magnitude in phase difference decreases). When the phase difference

$$( \frac{π}{2} - \frac{β}{2} )$$

is a negative value (e.g., leading state), as the conduction angle β decreases, the phase difference may decrease (e.g., the magnitude in phase difference decreases). Accordingly, upon identifying that the phase difference between the voltage V_{AC} and current I_{AC} meets a designated condition (e.g., a predetermined magnitude or more), the electronic device 101 may increase the conduction angle of the transistor when the phase of the current (e.g., I_{AC}) is in the lagging state with respect to the voltage (e.g., V_{AC}) and decrease the conduction angle of the transistor when the phase of the current (e.g., I_{AC}) is in the leading state with respect to the phase of the voltage (e.g., V_{AC}). Thus, the voltage (e.g., V_{AC}) and current (e.g., I_{AC}) may be reduced.

According to various embodiments, an electronic device (e.g., the electronic device 101 of FIG. 1) may comprise a battery (e.g., the battery 309 of FIG. 3), a resonance circuit (e.g., the resonance circuit 301 of FIG. 3) including a coil and a capacitor and configured to wirelessly receive power, a rectification circuit (e.g., the rectification circuit 303 of FIG. 3) including a plurality of transistors and configured to rectify AC power provided from the resonance circuit into DC power, and a control circuit (e.g., the control circuit 311 of FIG. 3). The control circuit may be configured to identify a difference between a phase of voltage and a phase of current of the AC power provided from the resonance circuit while the power is wirelessly received from an external electronic device and perform impedance matching by controlling a bias voltage of at least one of the plurality of transistors based on the difference between the phase of voltage and the phase of current meeting a designated condition.

According to various embodiments, the plurality of transistors may configure a bridge circuit. Each of a plurality of switches of the bridge circuit may include two or more transistors connected in series or parallel.

According to various embodiments, the control circuit may be configured to control the bias voltage of the at least one of the plurality of transistors based on controlling gate voltages applied to the plurality of transistors included in the plurality of switches.

According to various embodiments, the control circuit may be configured to control again the bias voltage of the at least one of the plurality of transistors based on the difference between the phase of voltage and the phase of current meeting the designated condition and maintain the bias voltage of the at least one of the plurality of transistors based on the difference between the phase of voltage and the phase of current failing to meet the designated condition.

According to various embodiments, at least one of the plurality of transistors may be turned off based on controlling the gate voltages. The AC power may be rectified into the DC power as other transistors than the at least one transistor are turned off and turned on, with the at least one transistor turned off.

According to various embodiments, the control circuit may be configured to, if the difference between the phase of voltage and the phase of current meets the designated condition, control the plurality of switches to increase a capacitance of at least one switch among the plurality of switches based on the phase of current being in a lagging state with respect to the phase of voltage.

According to various embodiments, the control circuit may be configured to, if the difference between the phase of voltage and the phase of current meets the designated condition, control the plurality of switches to decrease a capacitance of the at least one switch based on the phase of current being in a leading state with respect to the phase of voltage.

According to various embodiments, the control circuit may be configured to, if the difference between the phase of voltage and the phase of current meets the designated condition, increase the bias voltage of at least one of the plurality of transistors based on the phase of current being in a lagging state with respect to the phase of voltage.

According to various embodiments, the control circuit may be configured to, if the difference between the phase of voltage and the phase of current meets the designated condition, decrease the bias voltage of at least one of the plurality of transistors based on the phase of current being in a leading state with respect to the phase of voltage.

According to various embodiments, a conduction angle of at least one of the plurality of transistors may be changed based on the bias voltage being controlled.

According to various embodiments, the control circuit may be configured to identify the difference between the phase of voltage and the phase of current, identify a degree of adjustment of the conduction angle of the at least one transistor based on the identified difference, and adjust the bias voltage of at least one of the plurality of transistors by a magnitude corresponding to the degree of adjustment based on identifying the degree of adjustment of the conduction angle.

According to various embodiments, a method for controlling an electronic device may comprise identifying a difference between a phase of voltage and a phase of current of AC power provided from a resonance circuit of the electronic device while the power is wirelessly received from an external electronic device and performing impedance matching by controlling a bias voltage of at least one of a plurality of transistors included in a rectification circuit of the electronic device based on the difference between the phase of voltage and the phase of current meeting a designated condition.

According to various embodiments, the plurality of transistors may configure a bridge circuit. Each of a plurality of switches of the bridge circuit may include two or more transistors connected in series or parallel.

According to various embodiments, performing the impedance matching by controlling the bias voltage of the at least one of the plurality of transistors may include controlling the bias voltage of the at least one of the plurality of transistors based on controlling gate voltages applied to the plurality of transistors included in the plurality of switches.

According to various embodiments, the method may further comprise controlling again the bias voltage of the at least one of the plurality of transistors based on the difference between the phase of voltage and the phase of current meeting the designated condition and maintaining the bias voltage of the at least one of the plurality of transistors based on the difference between the phase of voltage and the phase of current failing to meet the designated condition.

According to various embodiments, performing the impedance matching by controlling the bias voltage of the at least one of the plurality of transistors may include, if the difference between the phase of voltage and the phase of current meets the designated condition, controlling the plurality of switches to increase a capacitance of at least one switch among the plurality of switches based on the phase of current being in a lagging state with respect to the phase of voltage.

According to various embodiments, performing the impedance matching by controlling the bias voltage of the at least one of the plurality of transistors may include, if the difference between the phase of voltage and the phase of current meets the designated condition, controlling the plurality of switches to decrease a capacitance of the at least one switch based on the phase of current being in a leading state with respect to the phase of voltage.

According to various embodiments, performing the impedance matching by controlling the bias voltage of the at least one of the plurality of transistors may include, if the difference between the phase of voltage and the phase of current meets the designated condition, increasing the bias voltage of at least one of the plurality of transistors based on the phase of current being in a lagging state with respect to the phase of voltage. “Based on” as used herein covers based at least on.

According to various embodiments, performing the impedance matching by controlling the bias voltage of the at least one of the plurality of transistors may include, if the difference between the phase of voltage and the phase of current meets the designated condition, decreasing the bias voltage of at least one of the plurality of transistors based on the phase of current being in a leading state with respect to the phase of voltage.

According to various embodiments, a computer-readable non-volatile recording medium may store instructions to, when executed, enable at least one processor of an electronic device to identify a difference between a phase of voltage and a phase of current of AC power provided from a resonance circuit of the electronic device while the power is wirelessly received from an external electronic device and perform impedance matching by controlling a bias voltage of at least one of a plurality of transistors included in a rectification circuit of the electronic device based on the difference between the phase of voltage and the phase of current meeting a designated condition.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via at least a third element(s).

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC). Thus, each “module” herein may comprise circuitry.

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various embodiments, it will be understood that the various embodiments are intended to be illustrative, not limiting. It will further be understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

1. An electronic device, comprising:
a battery;
a resonance circuit including a coil and a capacitor, the resonance circuit configured to wirelessly receive power;
a rectification circuit including a plurality of transistors, the rectification circuit configured to rectify AC power provided from the resonance circuit into DC power; and
a control circuit, wherein the control circuit is configured to:
identify a difference between a phase of voltage and a phase of current of the AC power provided from the resonance circuit as the power is wirelessly received from an external electronic device; and
perform impedance matching at least by controlling a bias voltage of at least one of the plurality of transistors based on the difference between the phase of voltage and the phase of current meeting a designated condition.

2. The electronic device of claim 1, wherein a bridge circuit comprises the plurality of transistors, and wherein each of a plurality of switches of the bridge circuit includes at least two transistors connected in series or parallel.

3. The electronic device of claim 2, wherein the control circuit is configured to control the bias voltage of the at least one of the plurality of transistors based on controlling gate voltages applied to the plurality of transistors included in the plurality of switches.

4. The electronic device of claim 3, wherein the control circuit is configured to:
control the bias voltage of the at least one of the plurality of transistors based on the difference between the phase of voltage and the phase of current meeting the designated condition; and
maintain the bias voltage of the at least one of the plurality of transistors based on the difference between the phase of voltage and the phase of current failing to meet the designated condition.

5. The electronic device of claim 3, wherein the device is configured to turn off at least one of the plurality of transistors based on controlling the gate voltages, and so that the AC power is rectified into the DC power as other transistors than the at least one transistor are turned off and/or turned on, with the at least one transistor turned off.

6. The electronic device of claim 2, wherein the control circuit is configured to, based on the difference between the phase of voltage and the phase of current meeting the designated condition, control the plurality of switches to increase a capacitance of at least one switch among the plurality of switches based on the phase of current being in a lagging state with respect to the phase of voltage.

7. The electronic device of claim 2, wherein the control circuit is configured to, based on the difference between the phase of voltage and the phase of current meeting the designated condition, control the plurality of switches to decrease a capacitance of the at least one switch based on the phase of current being in a leading state with respect to the phase of voltage.

8. The electronic device of claim 1, wherein the control circuit is configured to, based on the difference between the phase of voltage and the phase of current meeting the designated condition, increase the bias voltage of at least one of the plurality of transistors based on the phase of current being in a lagging state with respect to the phase of voltage.

9. The electronic device of claim 1, wherein the control circuit is configured to, based on the difference between the phase of voltage and the phase of current meeting the designated condition, decrease the bias voltage of at least one of the plurality of transistors based on the phase of current being in a leading state with respect to the phase of voltage.

10. The electronic device of claim 1, wherein the device is configured to change a conduction angle of at least one of the plurality of transistors based on the bias voltage being controlled.

11. The electronic device of claim 10, wherein the control circuit is configured to:
identify the difference between the phase of voltage and the phase of current;
identify a degree of adjustment of the conduction angle of the at least one transistor based on the identified difference; and
adjust the bias voltage of at least one of the plurality of transistors by a magnitude corresponding to the degree of adjustment based on identifying the degree of adjustment of the conduction angle.

12. A method for controlling an electronic device, the method comprising:
identifying a difference between a phase of voltage and a phase of current of AC power provided from a resonance circuit of the electronic device while the power is wirelessly received from an external electronic device; and
performing impedance matching by at least controlling a bias voltage of at least one of a plurality of transistors included in a rectification circuit of the electronic device based on the difference between the phase of voltage and the phase of current.

13. The method of claim 12, wherein a bridge circuit comprises the plurality of transistors, and wherein each of a plurality of switches of the bridge circuit includes at least two transistors.

14. The method of claim of claim 13, wherein performing the impedance matching by at least controlling the bias voltage of the at least one of the plurality of transistors includes controlling the bias voltage of the at least one of the plurality of transistors based on controlling gate voltages applied to the plurality of transistors included in the plurality of switches.

15. A computer-readable non-volatile recording medium, storing instructions to, when executed, cause at least one processor of an electronic device to:
identify a difference between a phase of voltage and a phase of current of AC power provided from a resonance circuit of the electronic device while the power is wirelessly received from an external electronic device; and
perform impedance matching by at least controlling a bias voltage of at least one of a plurality of transistors included in a rectification circuit of the electronic device based on the difference between the phase of voltage and the phase of current.
